(19) United States
(12) Patent Application Publication
(10) Pub. No.: US 2017/0055373 A1
(43) Pub. Date: Feb. 23, 2017

(54) HEAT-DISSIPATING DEVICE AND MANUFACTURING METHOD THEREOF

(71) Applicant: Amulaire Thermal Technology, Inc., New Taipei City (TW)

(72) Inventors: CHUN-LUNG WU, New Taipei City (TW); MING-SIAN LIN, New Taipei City (TW); WEN-YUAN CHOU, New Taipei City (TW)

(21) Appl. No.: 14/830,295

(22) Filed: Aug. 19, 2015

(51) Int. Cl. H05K 7/20; B23P 15/26

(52) U.S. Cl. CPC H05K 7/20409; B23P 15/26

(57) ABSTRACT

A heat-dissipating device includes a base and a plurality of heat-dissipating members. The base is formed with a plurality of joint holes. Each heat-dissipating member has an inserting section and an exposed section connected with the inserting section. The inserting sections are inserted into the joint holes in a close fit manner, respectively. The exposed sections are exposed outside a top surface of the base. The ends of the inserting sections and the bottom surface of the base are welded by a friction stir welding (FSW) manner with a solid-state joining structure. The present disclosure also provides a method for manufacturing a heat-dissipating device, which joins the ends of the inserting sections and the bottom surface of the base by a friction stir welding manner.

### BACKGROUND OF THE INVENTION

1. Field of the Invention

The present invention is related to a heat-dissipating device and manufacturing method thereof. In particular, the present invention relates to a heat-dissipating device for dissipating redundant heat. The heat-dissipating device has a base and a plurality of separate heat-dissipating members, and the heat-dissipating members are assembled to the base by a welding method to become the heat-dissipating device.

2. Description of Related Art

Electronic equipment usually produces much redundant heat when operating. To remove the redundant heat quickly, heat-dissipating devices have been widely used in electronic equipment. The heat-dissipating device usually has a base to contact an electrical component which produced the heat, and a plurality of heat-dissipating fins on a top surface of the base. The heat from the electrical component is transferred to the base of the heat-dissipating device and then transferred to the heat-dissipating fins. Consequently, heat is dissipated to the surrounding by radiation, compelled convection, or natural convection. A positive correlation relationship exists between the total surficial area of the heat-dissipating fins and the total heat-transferring value. To increase the total heat-transferring value, one common method is trying to maximize the height and the density of the heat-dissipating fins. However, such a solution causes smaller gaps between the heat-dissipating fins and affects the convection.

The heat-transferring capacity of the heat-dissipating device usually increases following the ratio of the height and the gap of the heat-dissipating fins. If a high heat-dissipating capacity is required, it usually uses a welding-type heat sink. The conventional welding technology for manufacturing a welding-type heat sink includes braze welding, pressure welding, and mechanical assembly. Although a heat sink with high-density heat-dissipating fins can be obtained by braze welding or pressure welding, the filling materials cannot be avoided during the welding process. Thus, the welded portions have some certain disadvantages of heat-transfer resistance by the filling material, and cause a negative influence on the total heat-transferring capacity.

Therefore, it is desirable to propose a novel heat-dissipating device to overcome the above-mentioned problems.

### SUMMARY OF THE INVENTION

It is one objective of this invention to provide a heat-dissipating device, which increases the numbers of the heat-dissipating members of the heat-dissipating device, and raises the density and heat-dissipating area of the heat-dissipating members of the heat-dissipating device, so as to enhance the heat transferring capacity of the heat-dissipating device.

Another objective of the present disclosure is to provide a method of manufacturing a heat-dissipating device, which increases the numbers of the heat-dissipating members of the heat-dissipating device, and raises the density and heat-dissipating area of the heat-dissipating members of the heat-dissipating device, so as to enhance the heat transferring capacity of the heat-dissipating device. Further, the heat-dissipating members are well connected with the base.

In order to achieve the above objectives, according to one exemplary embodiment of the instant disclosure, the instant disclosure provides a heat-dissipating device, including a base formed with a plurality of joint holes, and a plurality of heat-dissipating members. Each of the heat-dissipating members has an inserting section and an exposed section connected to the inserting section. The inserting sections are correspondingly inserted in the joint holes in a closed fit manner. The exposed sections are exposed outside the top surface of the base. The bottom ends of the inserting sections and the bottom surface of the base are combined by a friction stir welding process and have a solid-state joining structure.

In order to achieve the above objectives, according to one exemplary embodiment of the instant disclosure, a method of manufacturing a heat-dissipating device is provided and includes the steps as follows:

providing a base, and forming a plurality of joint holes on the base;

providing a plurality of heat-dissipating members, each of the heat-dissipating members is formed with an inserting section and an exposed section connected to the inserting section;

inserting the inserting sections into the joint holes in a closed fit manner correspondingly, and exposing the exposed sections outside the top surface of the base;

welding the bottom ends of the inserting sections with the bottom surface of the base by a friction stir welding process; and

leveling the bottom surface of the base.

Thus, the instant disclosure has advantages as follows. The present disclosure can flexibly change the distribution locations of the heat-dissipating members on the base. The heat-dissipating members can be formed with different structural variation. The heat-dissipating members and the base can be assembled well, so as to provide better heat conductivity effect.

For further understanding of the instant disclosure, reference is made to the following detailed description illustrating the embodiments and examples of the instant disclosure. The description is for illustrative purpose only and is not intended to limit the scope of the claim.

### BRIEF DESCRIPTION OF THE DRAWINGS

FIG. 1A is a perspective view of heat-dissipating device of first embodiment according to the present disclosure;

FIG. 1B is a perspective view using a friction-stir welding method to weld the heat-dissipating device of a first embodiment according to the present disclosure;

FIG. 2A is a perspective view of heat-dissipating device of a second embodiment according to the present disclosure;

FIG. 2B is a perspective view using a friction-stir welding method to weld the heat-dissipating device of a second embodiment according to the present disclosure;

FIG. 3A is a perspective view of heat-dissipating device of a third embodiment according to the present disclosure;

FIG. 3B is an enlarged perspective view of a heat-dissipating member of the heat-dissipating device of a third embodiment according to the present disclosure;

FIG. 4A is a perspective view of heat-dissipating device of a fourth embodiment according to the present disclosure;

FIG. 4B is a perspective view of heat-dissipating members of the heat-dissipating device of a fourth embodiment according to the present disclosure;

FIG. 5A is a perspective exploded view of heat-dissipating device of a fifth embodiment according to the present disclosure;

FIG. 5B another perspective exploded view of the heat-dissipating device of a fifth embodiment according to the present disclosure;

FIG. 6A is a perspective view of heat-dissipating device of a sixth embodiment according to the present disclosure;

FIG. 6B is a perspective view using a friction-stir welding method to weld the heat-dissipating device of a sixth embodiment according to the present disclosure;

FIG. 7 is a perspective view of heat-dissipating device of a seventh embodiment according to the present disclosure;

FIG. 7A is a partial enlarged view of the “A” portion of FIG. 7 according to the present disclosure;

FIG. 8 is a top view of the heat-dissipating device of a seventh embodiment according to the present disclosure;

FIG. 8A is a rear view of heat-dissipating device of a seventh embodiment according to the present disclosure; and

FIG. 8B is a side view of heat-dissipating device of a seventh embodiment according to the present disclosure.

### DETAILED DESCRIPTION OF THE PREFERRED EMBODIMENTS

### First Embodiment

The aforementioned illustrations and following detailed descriptions are exemplary for the purpose of further explaining the scope of the instant disclosure. Other objectives and advantages related to the instant disclosure will be illustrated in the subsequent descriptions and appended drawings.

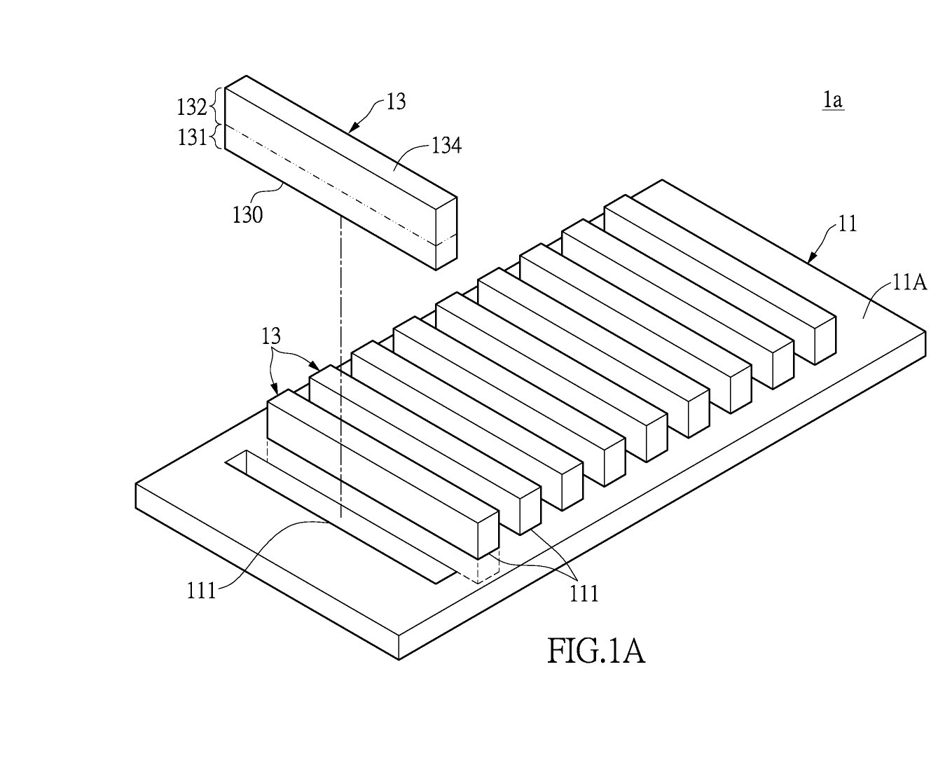

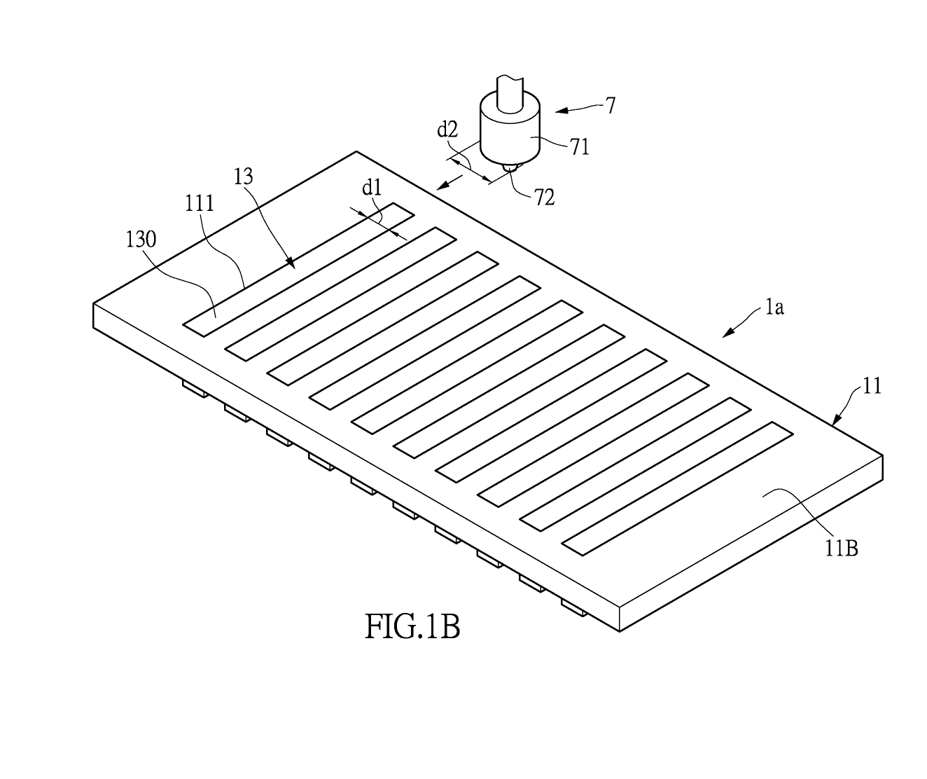

Refer to FIG. 1A and FIG. 1B. According to one embodiment of the present disclosure, a heat-dissipating device 1a includes a base 11 and a plurality of heat-dissipating members 13. The base 11 is formed with joint holes 111. Each heat-dissipating member 13 has an inserting section 131, and an exposed section 132 connected to the inserting section 131. The inserting sections 131 are inserted in the joint holes 111 correspondingly in a close fit manner, so that the exposed sections 132 are exposed outside the top surface 11A of the base 11. The bottom end 130 of the inserting section 131 and the bottom surface 11B of the base 11 are connected by the way of friction stir welding (FSW), so as to form a solid-state joining structure without tin solder. The heat-dissipating members 13 in this embodiment are just one example, which can be formed with a different shape and structure according to the requirements, such as a fins shape, small-posts shape, or slice shape . . . etc. The slice shape can be spiral or line. There are illustrative embodiments later in the application.

Refer to FIG. 1B. The bottom ends 130 of the inserting sections 131 can be aligned to the bottom surface 11B of the base 11, however the invention is not limited thereto. The top ends 134 of the exposed sections 132 preferably are arranged on a plane. The plane can be used to prop up and support the heat-dissipating members 13 by a fixing tool when applying the friction stir welding process.

This embodiment utilizes the friction stir welding process to manufacture the heat-dissipating device, which assembles the base 11 and the heat-dissipating members 13 by welding. Alternatively, the present disclosure can use other welding methods, and the friction stir welding process is only a preferable method. The method of manufacturing the heat-dissipating device includes the steps as follows. First, a base 11 is provided, and a plurality of joint holes 111 is formed on the base 11. The way to form the joint holes 111 can be punching or drilling . . . etc. Then, a plurality of heat-dissipating members 13 is provided. Each of the heat-dissipating members 13 is formed with an inserting section 131 and an exposed section 132 connected with the inserting section 131. The portion which is inserted in the base 11 is the inserting section 131.

The first step of assembling is to insert the plural inserting sections 131 into the plural joint holes 111 in a closed fit manner correspondingly, and the exposed sections 132 are exposed outside the top surface of the base 11. The objective of adopting the closed fit manner is to make the inserting sections 131 to be preliminarily fixed on the base 11.

Then, adopting the friction stir welding process to weld the bottom ends 130 of the inserting sections 131 and the bottom surface 11B of the base 11. The friction stir welding is one method of solid-state joining by the action of mechanical force and frictional heat, and joins two identical or different materials together by rotating a friction-stir tool 7. In this embodiment, the friction stir welding process includes at least one friction-stir tool (also called a welding tool) 7. Each friction-stir tool 7 has a shoulder portion (tool shoulder) 71 and a welding pin (stir probe) 72 which is protruded outside the shoulder portion 71. An outer diameter d2 of the shoulder portion 71 is larger than a width d1 of the joint hole 111 along a moving direction of the friction-stir tool 7. As shown in FIG. 1B, during the friction stir welding process, the bottom surface 11B of the base 11 is preferably arranged upward.

The principle of the friction stir welding process is described as follows. During the welding process, the friction-stir tool 7 is not only rotating, but also exerting a downward force simultaneously. The rotating friction-stir tool 7 slowly inserts into the working piece, which here is the bottom surface 11B of the base 11 and the heat-dissipating members 13. Then, the friction-stir tool 7 further moves forward along the welding area. The frictional shearing resist force between the friction-stir tool 7 and the working piece produce frictional heat, so that a periphery area of the working piece around the friction-stir tool 7 is heated to a temperature close to the melting point of the working piece. When the friction-stir tool 7 is rotating and moving forward, the metallic material around the friction-stir tool 7 is treated by the frictional heat and pressure between the shoulder portion 71 of the friction-stir tool 7 and the base 11, and form a fine and dense solid-state jointing. Through moving the friction-stir tool 7 back and forth, all of the heat-dissipating members 13 can be jointed to the base 11 in solid state.

During the process of friction stir welding, a force needs to be exerted at the side opposite to the friction-stir tool 7 to support the heat-dissipating device 1a. In this embodiment the top ends 134 of the exposed sections 132 are arranged on a sustaining plane of a tool, so that the sustaining plane can provide good support during welding process. Besides, the heat-dissipating members 13 of this embodiment are fixed in the joint holes 111 of the base 11 in a closed fit manner, so that the joint holes 111 provide the heat-dissipating members 13 with a good fixing result in a traverse direction. Even if the friction-stir tool 7 exerts force on the heat-dissipating members 13 as it is moving, it will not cause the heat-dissipating members 13 to move. In this embodiment, it only needs to support and block a side of the base 11 opposite to the friction-stir tool 7, and to retain the top ends 134 of the heat-dissipating members 13 upside down.

Since there are rotation traces after the frictional stir welding process, this embodiment can further level the bottom surface 11B of the base 11. For example, a milling cutter of a milling machine can be used to mill and level the bottom surface 11B of the base 11.

This embodiment therefore can flexibly change the locations of the heat-dissipating members 13 distributed on the base 11. The heat-dissipating members 13 could even have different heights, or other various modifications, so that they can be flexibly adapted to a heat-dissipating element and its mechanical structure.

### Second Embodiment

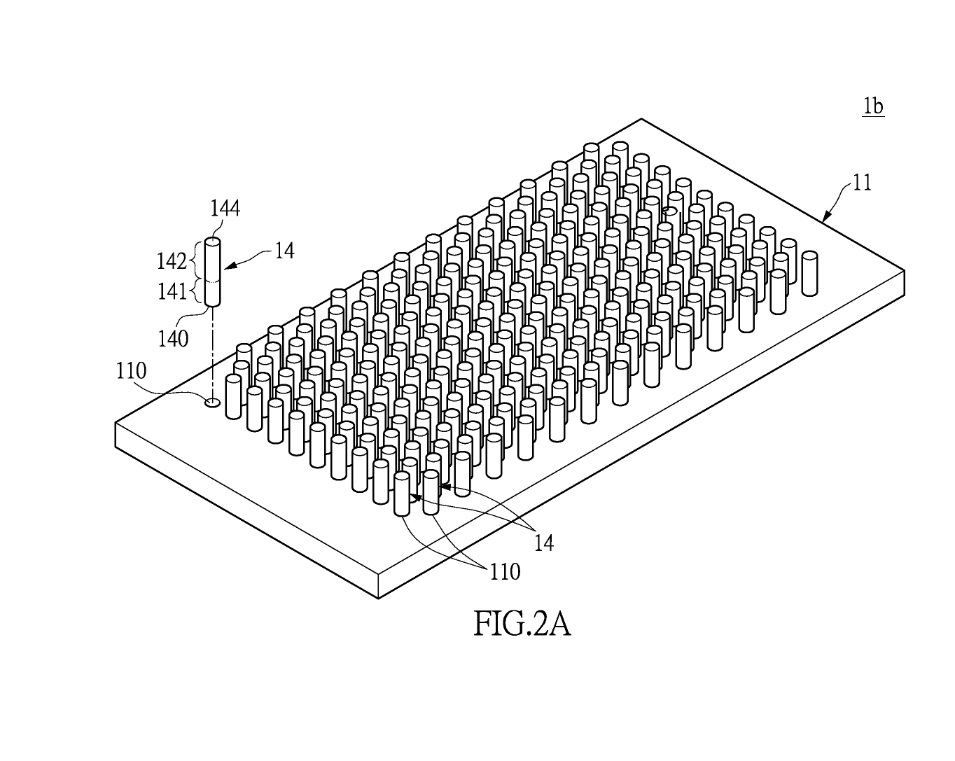

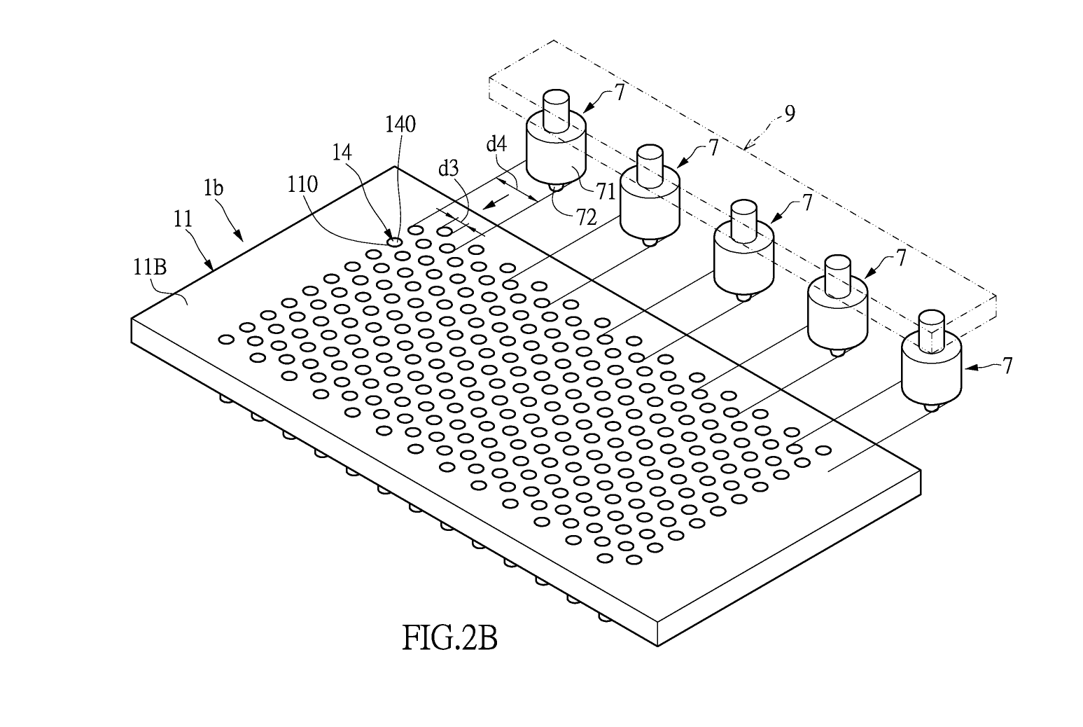

Refer to FIG. 2A and FIG. 2B, which are perspective views of a heat-dissipating device using a friction-stir welding method of a second embodiment. The difference between this embodiment and the above-mentioned embodiment is that, a heat-dissipating device 1b has a plurality of heat-dissipating members 14 with different shapes. The heat-dissipating members 14 are cylinder-shaped. Each of the heat-dissipating members 14 also has an inserting section 141 and an exposed section 142. The top ends 144 of the heat-dissipating members 14 are substantially planar-shaped. Further, the base 11 has a plurality of joint holes 110 matching the heat-dissipating members 14. The heat-dissipating members 14 are first assembled in the joint holes 110 in a closed fit manner.

One advantage of this embodiment is that the numbers of the heat-dissipating members 14 can be more than the embodiment above. During the process of frictional stir welding, the heat-dissipating members 14 can be fixed well in the joint holes 110 of the base 11. Further, the downward pressure of the friction-stir tool 7 can be distributed over the heat-dissipating members 14 separately, so as to prevent the heat-dissipating members 14 from being curved and having deformation.

Refer to FIG. 2B, which is a perspective view showing a method of manufacturing the heat-dissipating device of a second embodiment according to the present disclosure. The bottom ends 140 of the heat-dissipating members 14 are substantially aligned and flushed with the bottom surface 11B of the base 11. Concerning the steps of the frictional stir welding process, a plurality of friction-stir tools 7 can be provided at one time and placed side by side to frictional-stir weld the bottom surface 11B of the base 11 with the inserting sections 141 in the joint holes 110. Thus, the heat-dissipating members 14 can be quickly jointed with the base 11. This embodiment utilized a driving device 9 to link and drive the friction-stir tools 7. The driving device 9 can be a milling machine or drilling machine with a plurality of drills, which can be combined with a epicyclic gear (planetary gear) system, belt pulley (roller), or connecting rods . . . etc. so as to drive the friction-stir tools 7 to rotate simultaneously. The quantity of the friction-stir tools 7 depends on the width of the base 11, and a coverage range of the shoulder portion 71 of the friction-stir tools 7. In this embodiment, the joint hole 110 has a smaller internal diameter 18, and the outer diameter d4 of the shoulder portion 71 generally can cover three times the width d3 of the joint hole 110 along a moving direction of the friction-stir tool 7.

The plurality of friction-stir tools 7 can be arranged in at least two rows in a front and rear manner, and the coverage area of the shoulder portions 71 along the moving direction of the friction-stir tool 7 can be overlapped partially to each other. Therefore, the bottom surface 11B of the base 11 can be covered wholly, and all the heat-dissipating members 14 can be welded on the base 11 at one time.

Refer to FIG. 2B. The plurality of friction-stir tools 7 can be arranged separately at intervals, and a distance between two neighbor friction-stir tools 7 can be small or equal to one coverage range of the shoulder portion 71 of the friction-stir tool 7. When the plurality of shoulder portions 71 of the plurality of friction-stir tools 7 is riding atop the base 11 for the first time, the coverage width of the coverage range preferably is larger than or equal to one half of the base 11. Following this, the friction-stir tools 7 move transversely about a distance of one shoulder portion 71, then the friction-stir tools 7 are riding atop the base 11 for a second time to proceed with the frictional stir welding, so that all the heat-dissipating members 14 are welded to the base 11.

### Third Embodiment

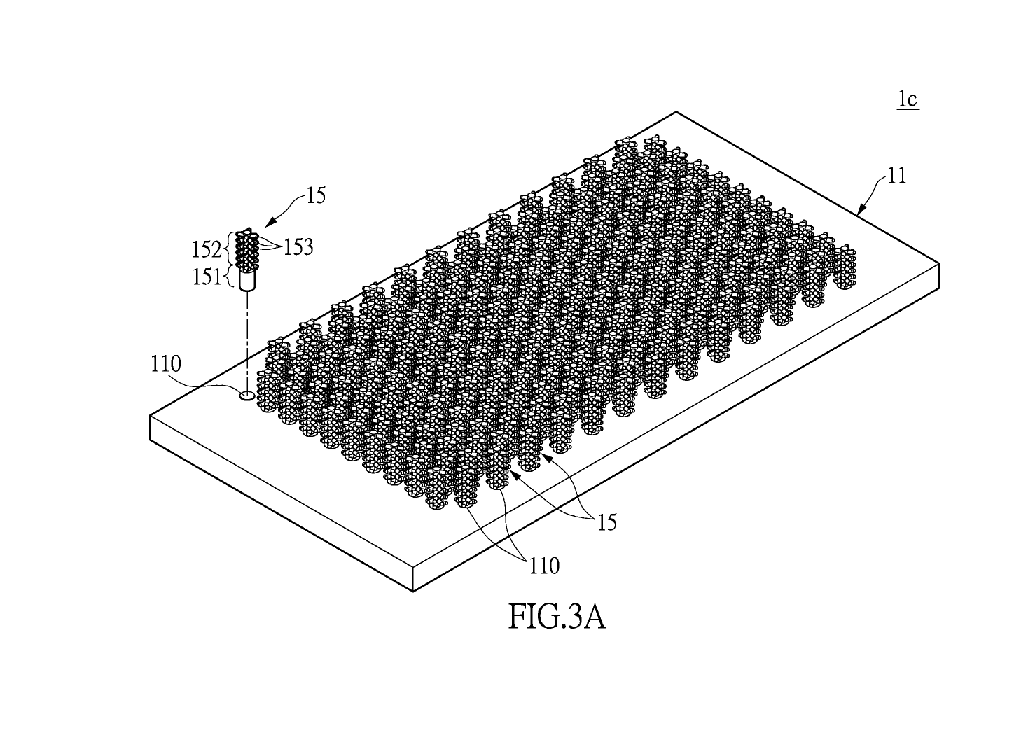

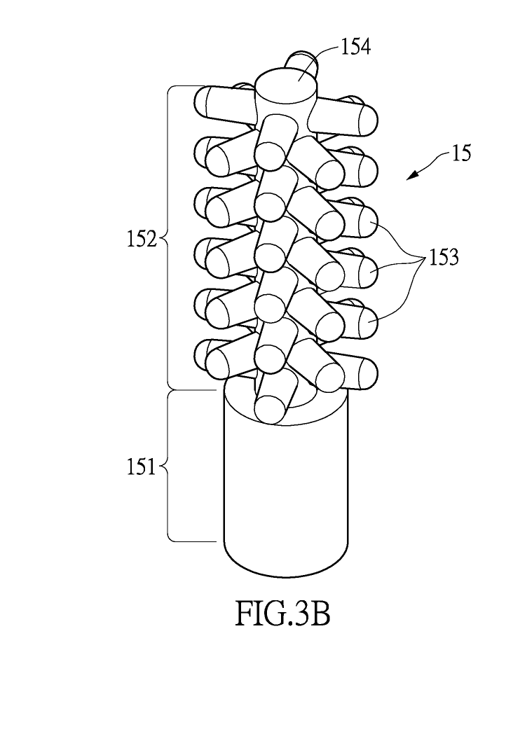

Refer to FIG. 3A and FIG. 3B, which are perspective views of a heat-dissipating device and a heat-dissipating member of a third embodiment according to the present disclosure. The difference of this embodiment and the second embodiment is that, the heat-dissipating device 1c has a plurality of heat-dissipating members 15 with a different appearance. Each heat-dissipating member 15 has an inserting section 151 and an exposed section 152. The top end 154 of the heat-dissipating members 15 is planar. Each heat-dissipating member 15 is formed with a micro-structural component 153 protruded from an outer surface of the exposed section 152. Each heat-dissipating member 15 is formed in a mace-shape, and there are small column-shaped micro-structural components 153. The advantage of this embodiment is that, the micro-structural components 153 can greatly increase the heat-dissipating area, so as to improve the cooling efficiency. Such a structure is hard to achieve by a conventional heat-dissipating device.

In this embodiment, an outer diameter of the inserting section 151 near to the micro-structural components 153 is larger than an outer diameter of the inserting section 151 further away. Such an arrangement provides a fixing function when the heat-dissipating members 15 are plugged in the joint hole 110 of the base 11. In fact, all micro-structural components 153 have an identical outer diameter, but the present disclosure is not limited thereto. As a supplementary note, the heat-dissipating members 15 of the present disclosure could increase the diameter of the inserting section 151 from its bottom end toward its top end gradually, so that it is cone-shaped upside down. The joint hole could be formed correspondingly as cone-shaped. Such an arrangement also can provide a fixing function when the heat-dissipating members 15 are plugged. Alternatively, a segment difference can be formed between the exposed section and the inserting section. In other words, the width (or outer diameter) of the exposed section is larger than the width (or outer diameter) of the inserting section, which also can provide a fixing function.

### Fourth Embodiment

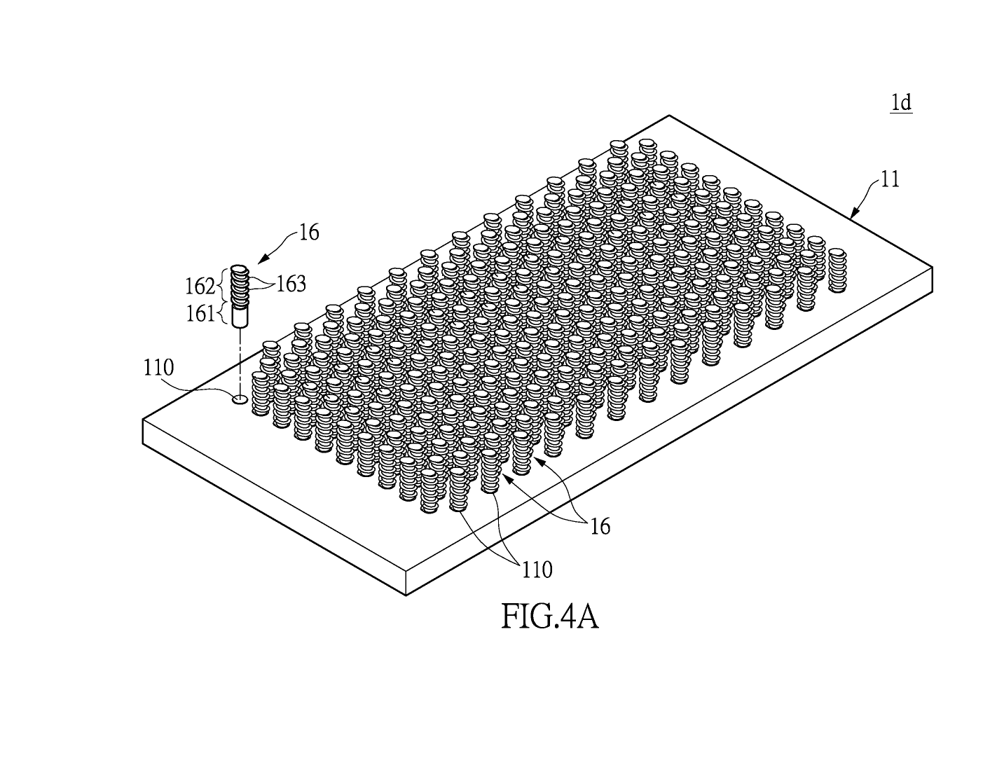

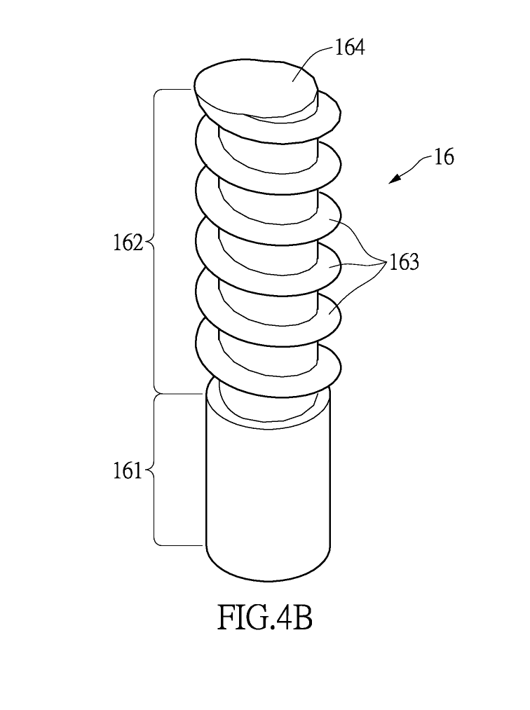

Refer to FIG. 4A and FIG. 4B, which are perspective views of the heat-dissipating device and a heat-dissipating member of a fourth embodiment of the present disclosure. The difference between this embodiment and the second embodiment is that, the heat-dissipating device 1d has a plurality of heat-dissipating members 16 with different shapes. The heat-dissipating member 16 has an inserting section 161 and an exposed section 162. The top end 164 of the heat-dissipating members 16 is planar shaped. Each heat-dissipating member 16 has a plurality of micro-structural components 163 protruded outward from an outer surface of the exposed section 162. Each of the heat-dissipating members 16 is shaped as a screw rod, and the micro-structural components 163 are spiral-shaped like a spiral staircase. This embodiment has advantages in that the micro-structural components 163 can greatly increase the area for dissipating heat, so as to enhance cooling efficiency. It is hard for the conventional heat-dissipating device to achieve such a large cooling area. The heat-dissipating members 16 can be made by mold casting or cutting by a latch.

### Fifth Embodiment

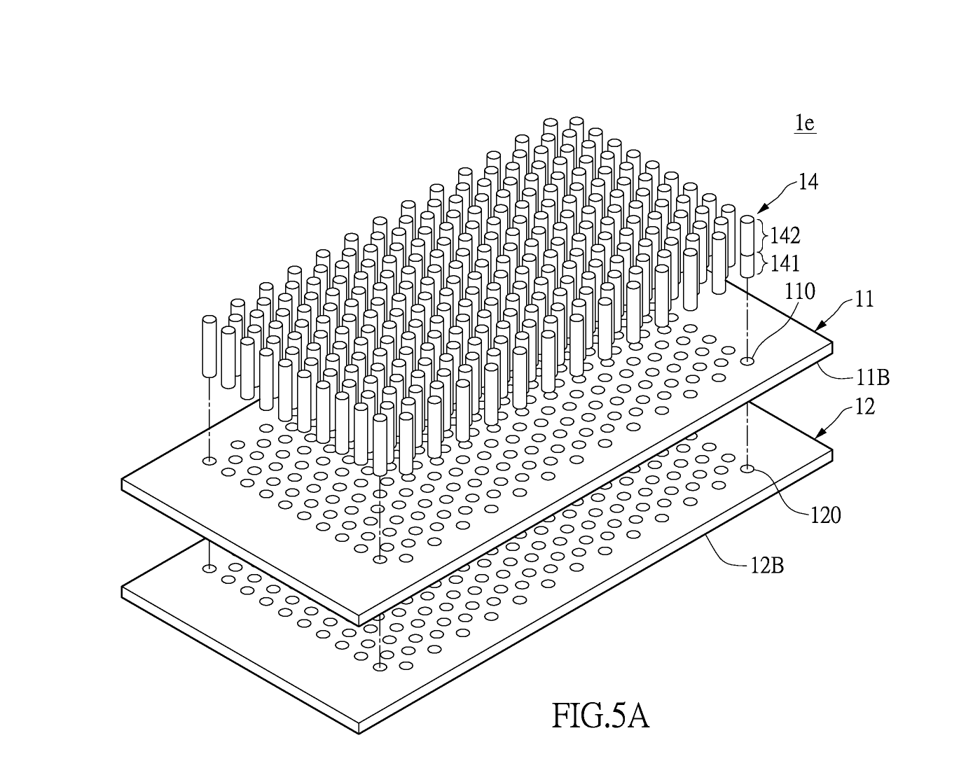

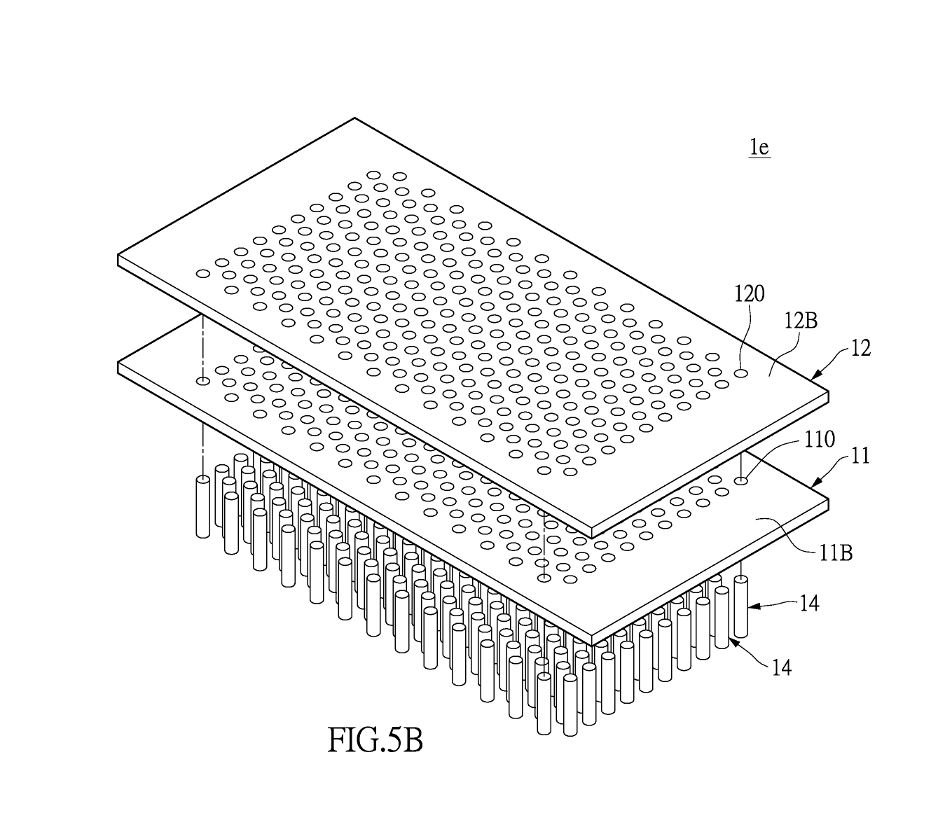

Refer to FIG. 5A and FIG. 5B, which are different perspective views of a heat-dissipating device of a fifth embodiment according to the present disclosure. Most of this embodiment is similar to the second embodiment. The difference includes that the base 11, the heat-dissipating members 14, and the heat-dissipating device 1e further has a secondary base 12 in contact with the bottom surface 11B of the base 11. The material of the secondary base 12 is different from the material of the base 11, such that the secondary base 12 has a thermal conductivity preferably larger than a thermal conductivity of the base 11. For example, the secondary base 12 is made of copper, and the base 11 is made of aluminum. The secondary base 12 is formed with a plurality of matching holes 120 corresponding to the joint holes 110 of the base 11. The inserting sections 141 of the heat-dissipating members 14 are respectively inserted in the joint holes 110 and the matching holes 120 in a closed fit manner. However, the secondary base 12 of this embodiment can be formed without any holes, and can contact directly with the bottom surface of the base 11. Further, the secondary base 12 can be used to strengthen the structural integrity. Based on different requirements, the present disclosure can add more secondary bases.

The bottom ends of the heat-dissipating members 14 preferably are aligned to the bottom surface 12B of the secondary base 12. The processes of the frictional stir welding are generally the same as the above embodiment, which further weld the secondary base 12 to join with the heat-dissipating members 14 and the base 11. Therefore, this embodiment can provide better heat conductivity effect.

### Sixth Embodiment

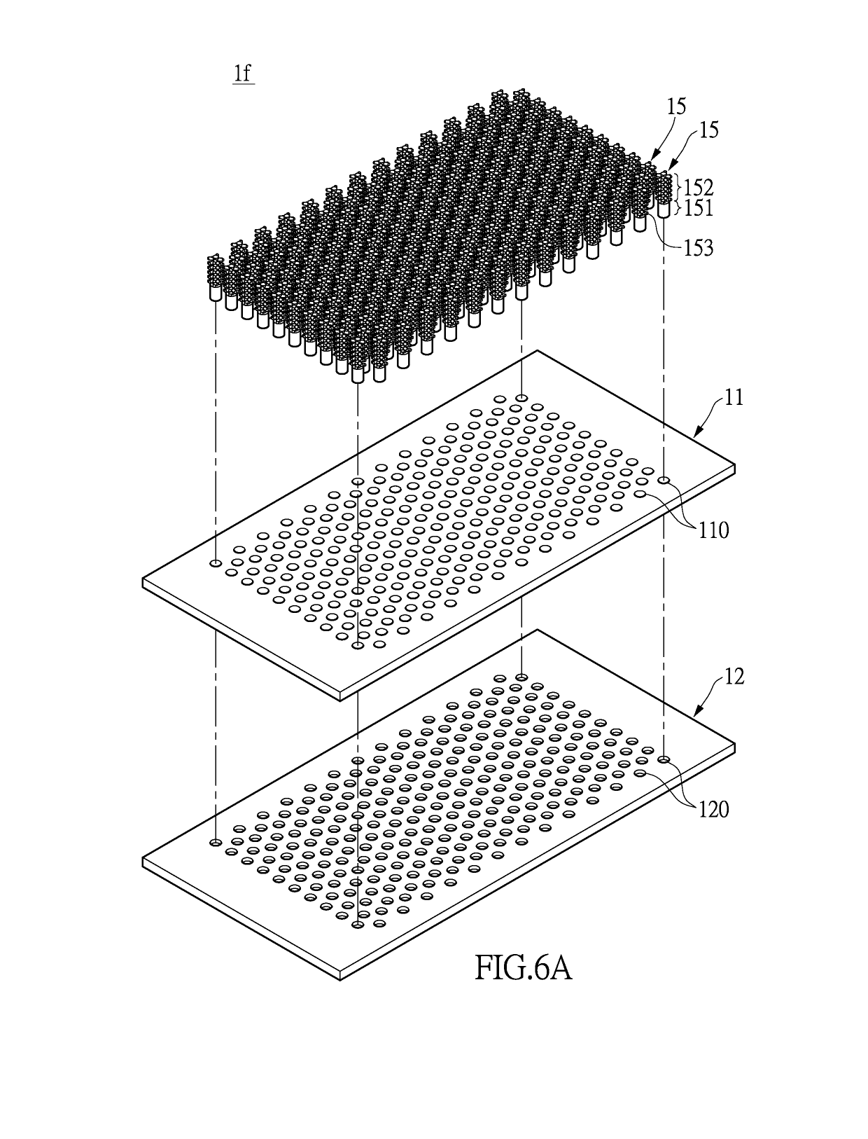

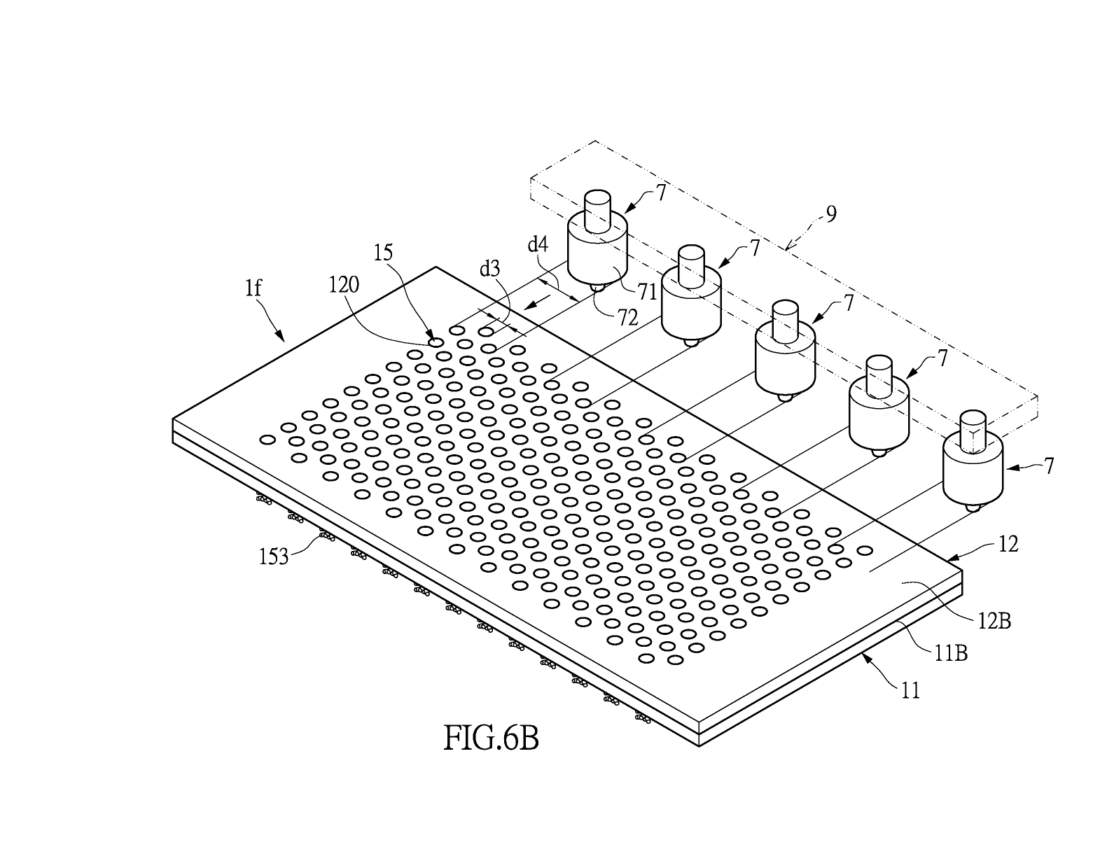

Refer to FIG. 6A and FIG. 6B, which are perspective views of a heat-dissipating device using a friction-stir welding method to weld the heat-dissipating device of a sixth embodiment according to the present disclosure. Most of this embodiment is similar as the fifth embodiment, with some differences as follows. The heat-dissipating device 1f has a plurality of heat-dissipating members 15 like that of the fifth embodiment. The heat-dissipating members 15 also have an inserting section 151 and an exposed section 152. Each heat-dissipating member 15 has a plurality of micro-structural components 153 protruded from an outer surface of the exposed section 152. Each heat-dissipating member 15 is mace-shaped, and the micro-structural components 153 are shaped as fine rods.

As shown in FIG. 6B, this embodiment can use the method of frictional stir welding as illustrated in the second embodiment, so it is not described again. Many friction-stir tools 7 are provided, and a driving device 9 is used to link and drive the friction-stir tools 7. Thus, it can complete the welding more quickly. Of course, this embodiment also can use the method of frictional stir welding as shown in FIG. 1B.

### Seventh Embodiment

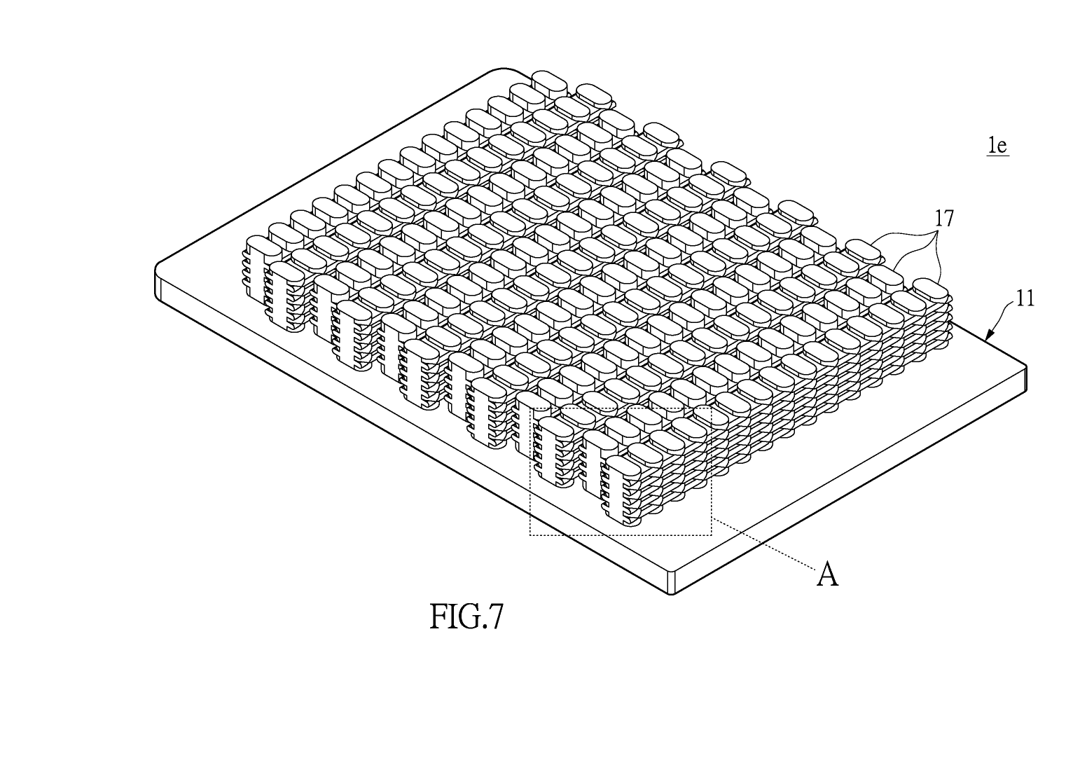

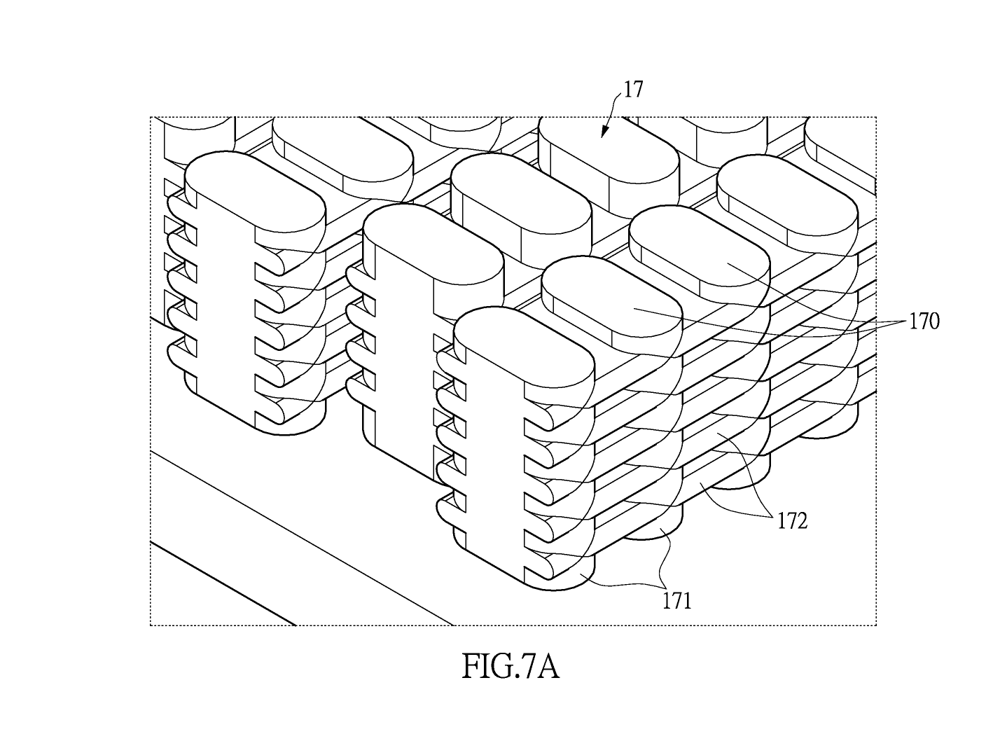

FIG. 7 is a perspective view of a heat-dissipating device of a seventh embodiment according to the present disclosure. The heat-dissipating device 1e has a plurality of strip-shaped parallel heat-dissipating members 17, which are fixed on the base 11. Please refer to FIG. 7A. Each heat-dissipating member 17 has a plurality of erected exposed sections 170, and a plurality of leaf portions 172 traversely arranged to connect the exposed sections 170. Each exposed section 170 has a bottom end extended with an inserting section 171, and the inserting section 171 is inserted into the base 11, so that both can be welded together by frictional stir welding process preferably. Therefore, the heat-dissipating members 17 can fixedly connect to the base 11.

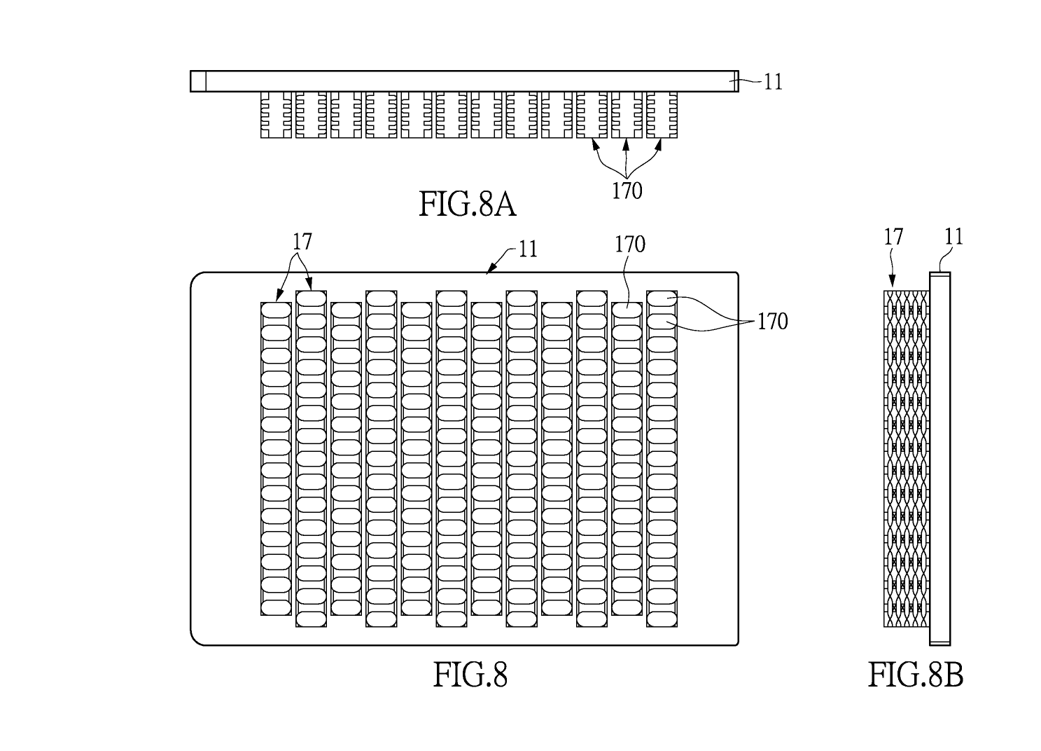

Refer to FIG. 8, FIG. 8A and FIG. 8B. In this embodiment, the exposed sections 170 of the heat-dissipating members 17 are substantially ellipse-shaped. Each heat-dissipating member 17 is kept at a gap from each other, so that it is good for air circulation between the exposed sections 170. In this embodiment, the exposed sections 170 are connected by the leaf portions 172, so that the heat-dissipating members 17 can be inserted row by row on the base 11 and the assembling process is quicker and time-saving. When it is frictional stir welding processed, the heat-dissipating members 17 are more easily fixed. As shown in FIG. 8, the exposed sections 170 at different rows of the heat-dissipating member 17 preferably are staggered relative to each other. In other words, two sides of each exposed section 170 are faced by the leaf portions 172 of the heat-dissipating members 17. As shown in FIG. 8A, the number of leaf portions 172 of alternating heat-dissipating members 17 are different. The leaf portions 172 at different rows of the heat-dissipating member 17 are staggered, so that air circulation is strengthened to enhance heat-dissipation.

The present disclosure has features and advantages as follows. The locations of the heat-dissipating members on the base can be flexibly changed, and even the heat-dissipating members can be formed with different heights. Therefore, it can be flexibly adapted to various electronic devices and mechanical structures. Further, the heat-dissipating member can be formed in different shapes, such as fin-shaped, fine-rod-shaped, or spiral-shaped micro-structural components (153, 163), to increase the heat-dissipating area with enhanced cooling efficiency. During the process of the friction stir welding, the joint holes of the base 11 provide good fixing function for the heat-dissipating members. The secondary base 12 with higher thermal conductivity can be jointed with the bottom surface of the base 11 to improve the cooling effect.

The descriptions illustrated supra set forth simply the preferred embodiments of the instant disclosure; however, the characteristics of the instant disclosure are by no means restricted thereto. All changes, alterations, or modifications conveniently considered by those skilled in the art are deemed to be encompassed within the scope of the instant disclosure delineated by the following claims.

What is claimed is:

1. A heat-dissipating device, comprising:
a base, formed with a plurality of joint holes; and
a plurality of heat-dissipating members, each heat-dissipating member has an inserting section and an exposed section connected with the inserting section, the inserting sections inserted in the joint holes in a close fit manner, the exposed sections exposed outside the top surface of the base, wherein the bottom ends of the inserting sections and the bottom surface of the base are joined by a friction stir welding process so as to form a solid-state joining structure without tin solder.

2. The heat-dissipating device as claimed in claim 1, wherein the top ends of the exposed sections are supported on a sustaining plane.

3. The heat-dissipating device as claimed in claim 1, wherein each of the exposed sections has a plurality of micro-structural components, the micro-structural components are protruded from an outer surface of the exposed section.

4. The heat-dissipating device as claimed in claim 3, wherein each of the micro-structural components is rod-shaped.

5. The heat-dissipating device as claimed in claim 3, wherein each of the micro-structural components is slice-shaped.

6. The heat-dissipating device as claimed in claim 3, wherein an outer diameter of the inserting section is larger than an outer diameter of the inserting section of the micro-structural component.

7. The heat-dissipating device as claimed in claim 1, further comprising a secondary base contacted with the bottom surface of the base, the material of the secondary base is different the material of the base.

8. A method for manufacturing heat-dissipating device, comprising steps as following:
providing a base, and forming a plurality of joint holes on the base;
providing a plurality of heat-dissipating members, each of the heat-dissipating members is formed with an inserting section and an exposed section connected to the inserting section;
inserting the inserting sections in the joint holes correspondingly in a close fit manner, and exposing the exposed sections outside the top surface of the base, each inserting section having a bottom end;
welding the bottom ends of the inserting sections to the bottom surface of the base by a friction stir welding process; and
leveling the bottom surface of the base 7.

9. The method for manufacturing a heat-dissipating device as claimed in claim 8, further comprising a step of forming a plurality of micro-structural components protruded outward from an outer surface of the exposed section of each heat-dissipating member.

10. The method for manufacturing a heat-dissipating device as claimed in claim 8, further comprising the steps as follows:
providing a secondary base contacted with the bottom surface of the base, and a material of the secondary base is different from a material of the base; and
forming a plurality of matching holes on the secondary base corresponding to the joint holes, wherein the inserting sections are respectively inserted into the joint holes and the matching holes.

11. The method for manufacturing a heat-dissipating device as claimed in claim 8, wherein the step of the friction stir welding process includes a step of providing at least one friction-stir tool, each of the friction-stir tools includes a shoulder portion and a welding pin protruded outside the shoulder portion.

12. The method for manufacturing a heat-dissipating device as claimed in claim 8, wherein the step of the friction stir welding process includes a step of providing a plurality of friction-stir tools, wherein the friction-stir tools are arranged side by side and weld the bottom surface of the base and the inserting section by stirring.
